(19) United States
(12) Patent Application Publication
(10) Pub. No.: US 2014/0125391 A1
(43) Pub. Date: May 8, 2014

(54) DUTY CYCLE CORRECTION APPARATUS

(71) Applicant: Jong Kug Seon, Suwon-si (KR)

(72) Inventor: Jong Kug Seon, Suwon-si (KR)

(73) Assignee: LSIS CO., LTD., Anyang-si Gyeonggi-do (KR)

(21) Appl. No.: 14/127,876

(22) PCT Filed: Jun. 25, 2012
(86) PCT No.: PCT/KR2012/004999

§ 371 Date: Dec. 19, 2013

(30) Foreign Application Priority Data
Jun. 24, 2011 (KR) 10-2011-0061881

(51) Int. Cl. H03K 3/017

(52) U.S. Cl. CPC H03K 3/017
USPC 327/175

(57) ABSTRACT

Disclosed is a duty cycle correction apparatus. The apparatus of the present invention adjusts signal widths of an input signal, averages the widths of the signal, and inverts the signal, then averages the widths of the inverted signal, compares the two averaged signals, and outputs the difference between the two averaged signals.

### TECHNICAL FIELD

The teachings in accordance with exemplary embodiments of this invention relate generally to an apparatus for correcting duty cycle.

### BACKGROUND ART

Generally, an apparatus for correcting duty cycle is a circuit widely used as a correction circuit in digital systems, a switching regulator used in a power circuit or a delay synchronous loop in a signal synchronous system, and serves to reduce an error rate by transmitting an accurate data through correction of a duty cycle of an internal or external clock signal.

That is, changes in duty ratio generated by a path delay or a reflection path are corrected by 50% in a digital system to enable a sampling signal of the system to accurately detect data. A switching regulator used in a power circuit functions to improve performances by adjusting accurate duty ratio of a switch. Furthermore, a duty ratio of received signal data is accurately adjusted and synchronized to improve reception sensitivity in a delay synchronous loop.

However, because it is imperative in a conventional duty cycle correction apparatus that a pulse generator be installed, disadvantages arise in which a complicated circuit is required for maintaining an accurate pulse width, and a scope for correcting a duty cycle is limited, for example. Another disadvantage is that a delayer used in a conventional duty cycle correction apparatus has an intrinsic delay error which further results in generation of inaccurate duty ratio.

### DISCLOSURE

### Technical Problem

Accordingly, the present invention has been made keeping in mind with the above disadvantages or problems occurring in the prior art, and an object of the present invention is to provide an apparatus for correcting duty cycle (hereinafter referred to as duty cycle correction apparatus, simply as the apparatus) configured to minimize an intrinsic error due to no use of a pulse generator or a delayer.

Another object of the present invention is to provide an apparatus for correcting duty cycle configured to minimize a degradation of system performances caused by changes in duty ratio of an input signal by designing a system insensitive to process changes and temperature changes.

### Technical Solution

An object of the invention is to solve at least one or more of the above problems and/or disadvantages in whole or in part and to provide at least the advantages described hereinafter. In order to achieve at least the above objects, in whole or in part, and in accordance with the purposes of the invention, as embodied and broadly described, and in one general aspect of the present invention, there is provided an apparatus for correcting duty cycle (hereinafter referred to as duty cycle correction apparatus, simply as the apparatus), the apparatus configured to correct a duty ratio of an input signal, the apparatus comprising: an alert clock configured to adjust a signal width of the input signal; a first equalization unit configured to equalize a width of an output signal of the alert clock; an inverter configured to reverse the output signal of the alert clock; a second equalization unit configured to equalize a width of an output signal of the inverter; and a comparator configured to compare the output signals of the first and second equalization units, and output a difference between the output signals of the first and second equalization units.

In some exemplary of the present invention, the alert clock may be configured to adjust the width of the input signal using an output of the comparator.

In some exemplary of the present invention, the apparatus may further comprise a selector configured to select a ratio of the output signals of the first and second equalization units to allow the comparator to output the difference in response to the ratio.

In some exemplary of the present invention, the apparatus may further comprise a first buffer configured to temporarily store an output of the alert clock and output the output of the alert clock to the first equalization unit.

In some exemplary of the present invention, the inverter may be configured to reverse an output of the first buffer.

In some exemplary of the present invention, the apparatus may further comprise a second buffer configured to temporarily store and output an output of the first buffer.

In some exemplary of the present invention, the output of the comparator is inputted to the alert clock until the output of the comparator substantially becomes zero, when a duty ratio of the output of the alert clock matches that of the output of the inverter.

In some exemplary of the present invention, the alert clock comprises: a controller configured to control the width of input signal in response to the output of the comparator, and a first switch configured to turn on or off operation of the controller.

In some exemplary of the present invention, each of the first and second equalization units comprises: a current source configured to supply a current, a second switch configured to switch the current supplied from the current source in response to high and low level of an inputted voltage, and an LPF (Low Pass Filter) configured to equalize a width of the voltage inputted using the current of the current source in response to the switching of the second switch and to output the equalized width.

In some exemplary of the present invention, the LPF may include a capacitor.

### Advantageous Effects

The apparatus for correcting duty cycle according to the present invention has an advantageous effect in that system can be miniaturized and power consumption can be reduced due to non-use of a pulse generator conventionally used in a duty cycle correcting apparatus.

Another advantageous effect is that a delayer that generates an intrinsic delay error is not used to greatly increase accuracy.

### DESCRIPTION OF DRAWINGS

FIG. 1 is a block diagram illustrating a configuration of an apparatus for correcting duty cycle according to prior art.

FIG. 2 is a schematic view illustrating signal cycles at each node of FIG. 1.

FIG. 3 is a block diagram illustrating a configuration of an apparatus for correcting duty cycle according to the present invention.

FIG. 4a is a detailed view of a duty-alert clock of FIG. 3 according to an exemplary embodiment of the present invention.

FIG. 4b is a circuit diagram illustrating an actual enablement of FIG. 4a according to an exemplary embodiment of the present invention.

FIG. 5a is a detailed view of a duty-alert clock of FIG. 3 according to another exemplary embodiment of the present invention.

FIG. 5b is a circuit diagram illustrating an actual enablement of FIG. 5a according to an exemplary embodiment of the present invention.

FIGS. 6 and 7 are detailed configuration views of an average value detector of FIG. 3 according to an exemplary embodiment of the present invention.

FIG. 8 is an input waveform of the average value detector of FIGS. 6 and 7 according to an exemplary embodiment of the present invention, and

FIG. 9 is a block diagram illustrating a configuration of an apparatus for correcting duty cycle according to a second exemplary embodiment of the present invention.

### BEST MODE

The following description is not intended to limit the invention to the form disclosed herein. Consequently, variations and modifications commensurate with the following teachings, and skill and knowledge of the relevant art are within the scope of the present invention.

The embodiments described herein are further intended to explain modes known of practicing the invention and to enable others skilled in the art to utilize the invention in such, or other embodiments and with various modifications required by the particular application(s) or use(s) of the present invention.

It will be understood that, although the terms first, second, etc. may be used herein to describe various elements, components, regions, layers, and/or sections, these elements, components, regions, layers, and/or sections should not be limited by these terms.

These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

It will be understood that when an element is referred to as being “connected” or “coupled” to another element, it can be directly connected or coupled to the other elements or intervening elements may be present. In contrast, when an element is referred to as being “directly connected” or “directly coupled” to another element, there are no intervening elements present.

As used herein, the singular forms “a”, “an” and “the” are intended to include the plural forms as well, unless the context clearly indicates otherwise.

It will be understood that the terms “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. That is, the terms “including”, “includes”, “having”, “has”, “with”, or variants thereof are used in the detailed description and/or the claims to denote non-exhaustive inclusion in a manner similar to the term “comprising”.

Furthermore, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated. That is, in the drawings, the size and relative sizes of layers, regions and/or other elements may be exaggerated or reduced for clarity. Like numbers refer to like elements throughout and explanations that duplicate one another will be omitted. Words such as “thereafter,” “then,” “next,” “therefore”, etc. are not intended to limit the order of the processes; these words are simply used to guide the reader through the description of the methods.

Hereinafter, an apparatus for correcting duty cycle according to prior art will first described and an apparatus for correcting duty cycle according to the present invention will be described later with reference to the accompanying drawings.

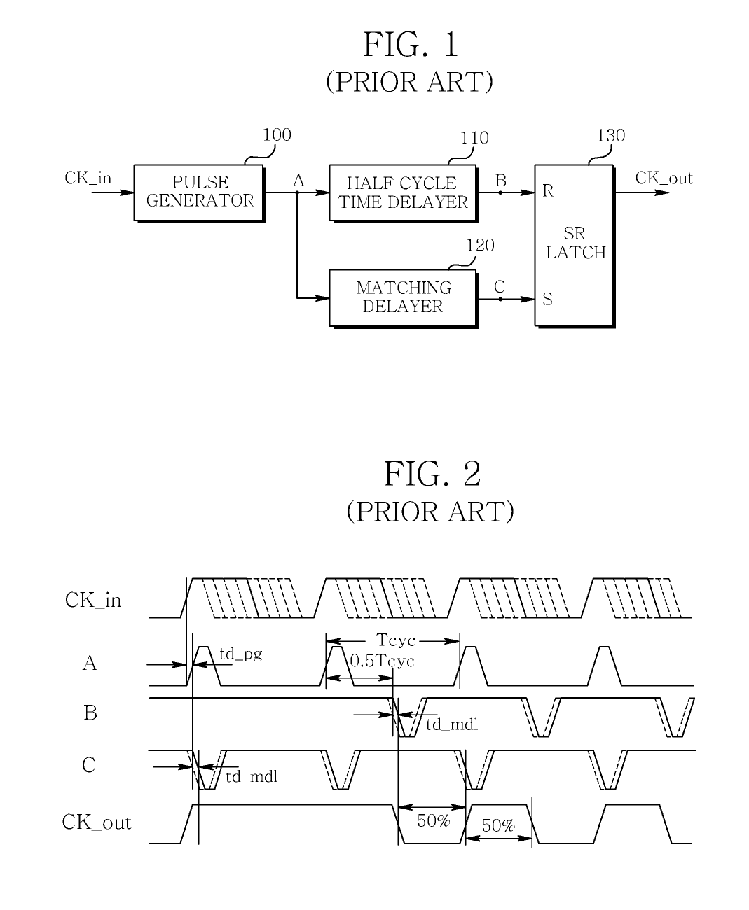

FIG. 1 is a block diagram illustrating a configuration of an apparatus for correcting duty cycle (hereinafter referred to as duty cycle correction apparatus, or simply as the apparatus) according to prior art, and FIG. 2 is a schematic view illustrating signal cycles at each node of FIG. 1.

Referring to FIGS. 1 and 2, the apparatus according to prior art may include a pulse generator (100), a half cycle time delayer (110), a matching delayer (120) and an SR (Set-Reset) latch (130).

Referring to FIGS. 1 and 2 again, the pulse generator (100) generates a pulse at a rising edge of CK_in relative to an input signal CK_in having an inaccurate duty ratio.

The half cycle time delayer (110) generates a reversal signal over a half cycle delay time of the pulse generator (100).

The matching delayer (120) corrects an error generated by an intrinsic delay of the half cycle time delayer (110) to generate a reversal signal relative to the pulse generator (100).

The SR latch (130) repeats rising and falling at the moment of risings and fallings of output signals of the half cycle time delayer (110) and the matching delayer (120), and outputs an output signal CK-out having an accurate duty ratio relative to the signal CK_in having an inaccurate duty ratio.

As noted from the foregoing, the duty cycle correction apparatus according to prior art requires a pulse generator (100) to disadvantageously complicate a circuit for maintaining an accurate pulse width. Another disadvantage is that a width of the pulse generator (100) grows inaccurate, when a duty ratio of input signal CK_in is low, and an error of duty ratio changes in time to limit a scope capable of correcting a duty cycle.

Still another disadvantage is that the duty cycle correction apparatus according to prior art is such that a delayer such as a half cycle time delayer (110) or a matching delayer (120) has an intrinsic delay error, and the error makes the duty ratio further inaccurate.

In order to solve the abovementioned problems in the prior art, the present invention dispenses with a pulse generator in designing a duty cycle correction apparatus and also dispenses with a delayer for minimizing an intrinsic delay error generated by the delayer.

The present invention is designed to be insensitive to process changes and temperature changes, and minimizes the performance degradation of a system caused by changes in duty ratio of input signal. Furthermore, power consumption is minimized to allow the duty cycle correction apparatus according to the present invention to be applied to various fields. Hereinafter, the duty cycle correction apparatus according to the present invention will be described in details.

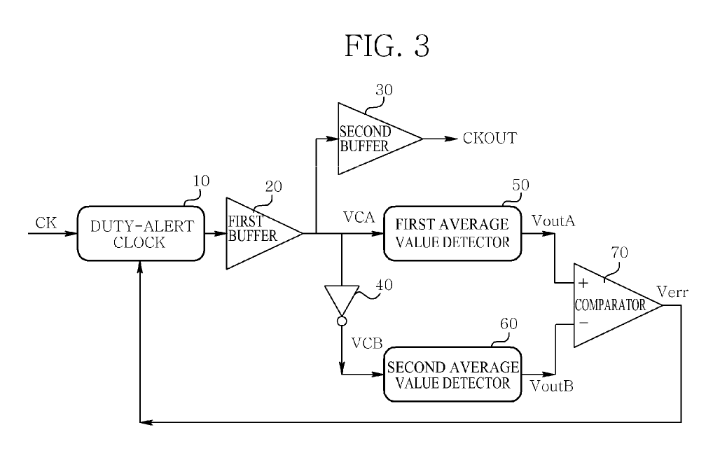

FIG. 3 is a block diagram illustrating a configuration of an apparatus for correcting duty cycle according to the present invention.

Referring to FIG. 3, the apparatus may include a duty alert clock (10), a first buffer (20), a second buffer (30), an inverter (40), a first average value detector (50), a second average value detector (60) and a comparator (70).

The duty alert clock (10) adjusts a signal width in response to the size of an output signal Verr detected by the comparator (70) when an input signal CK having an inaccurate duty ratio is inputted.

The first buffer (20) temporarily stores an output of the duty alert clock (10), and then outputs the output, and the second buffer (30) temporarily stores an output of the first buffer (2) and then outputs the output of the first buffer (20). The output of the second buffer (30) may be used as a signal for checking the output of the duty alert clock (10).

The first average value detector (50) equalizes a width of an output VCA of the duty alert clock (10).

The inverter (40) outputs a VCB by reversing the output of the first buffer (20).

The second average value detector (60) equalizes a width of output VCB of the inverter (40).

The outputs VoutA and VoutB of the first and second average value detectors (50, 60) are compared in turn by the comparator (70), where the compared output is provided to the duty alert clock (10).

Now, the above process will be explained by a signal flow. When an input signal CK having an inaccurate duty ratio is inputted to the duty alert clock (10), a width of the input signal is adjusted in response to a size of the output Verr detected by the comparator (70), the output VCA thereof is equalized by the first average value detector (50), and the signal VCB reversed by the inverter (40) is equalized by the second average value detector (60), and re-compared by the comparator (70).

The abovementioned process is repeated until the output signal Verr detected by the comparator (70) grows to zero in a system of 50% duty ratio where duty ratio of VCA and duty ratio of VCB are completely matched. The apparatus according to the present invention can adjust a duty ratio accurately through this process, even if a pulse generator or a delayer is not used.

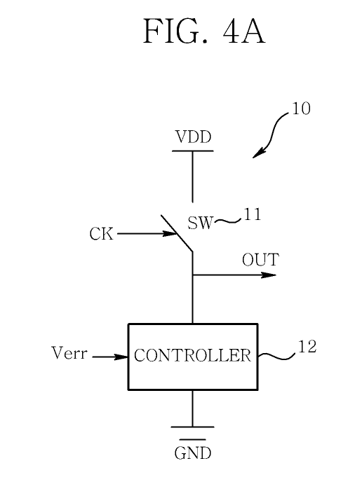

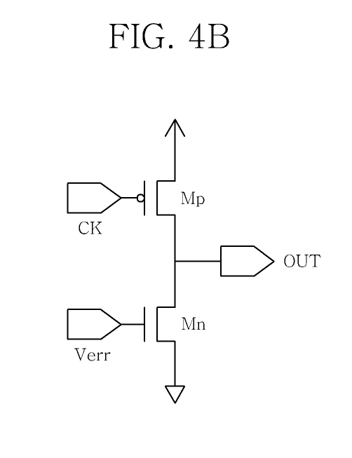

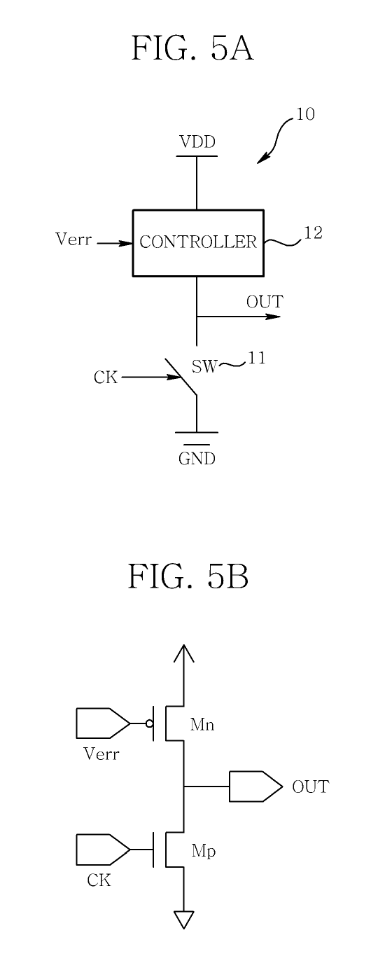

FIG. 4a and FIG. 5a are respectively detailed views of a duty-alert clock of FIG. 3 according to an exemplary embodiment of the present invention, and FIG. 4b and FIG. 5b are respectively circuit diagrams illustrating an actual enablement of FIG. 4a and FIG. 5a according to an exemplary embodiment of the present invention.

Referring to FIGS. 4a and 5a, the duty alert clock (10) of the apparatus according to an exemplary embodiment of the present invention may include switches (SW, 11) configured to turn on/off operation of a controller (12), and the controller (12) configured to adjust a voltage or a current. FIGS. 4a and 5a are same in configuration but illustrate examples where arrangements are different.

The controller (12) adjusts a width of input signal CK in response to the output Verr of the comparator (70).

Although the actual enablement of FIG. 4a and the actual enablement FIG. 5a are same as those of FIG. 4b and FIG. 5b, a transistor Mp is used as the switch (11) and a transistor Mn is used as the controller (12) in the exemplary embodiment of the present invention.

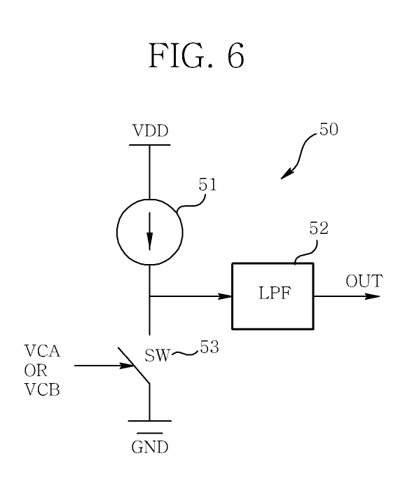

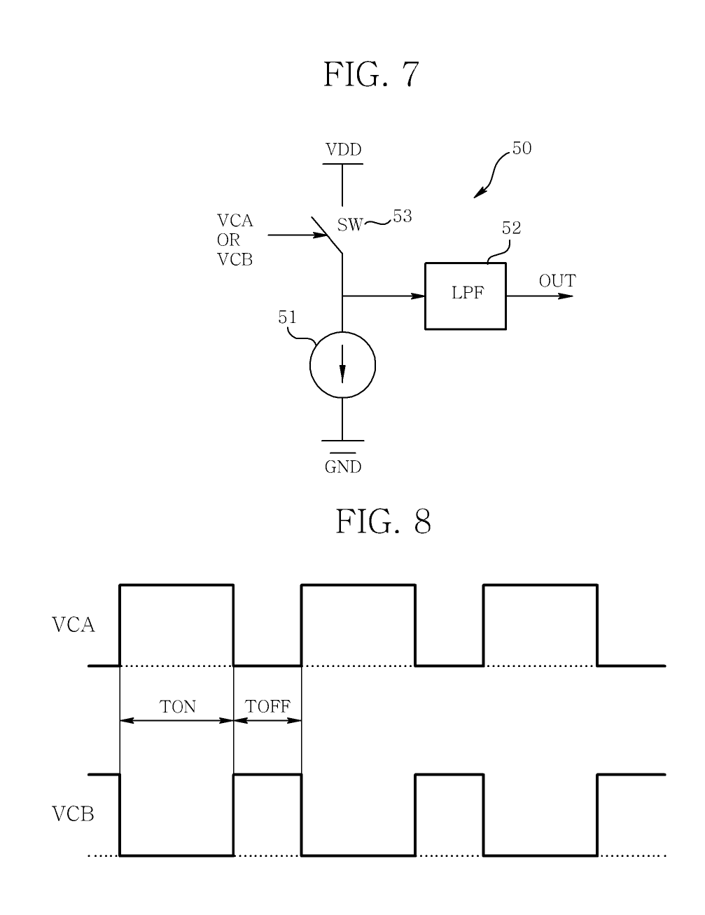

FIGS. 6 and 7 are detailed configuration views of an average value detector of FIG. 3 according to an exemplary embodiment of the present invention, where the first and second average value detectors (50, 60) of FIG. 3 may be also used. For convenience sake, although an explanation will be provided using the first average value detector (50), it should be noted that the second average value detector (60) is not ruled out from the explanation of the present invention.

Referring to FIGS. 6 and 7, the first average value detector (50) in the apparatus according to an exemplary embodiment of the present invention may include a current source (51), an LPF (Low Pass Filter, 52) and a switch (53). Although FIGS. 6 and 7 are same in configuration, FIGS. 6 and 7 illustrate exemplary embodiments where arrangements are different.

FIG. 8 is an input waveform of the first average value detector (50) of FIGS. 6 and 7 according to an exemplary embodiment of the present invention, where a switch (53) repeats turn-on and turn-off as much as a width of an output signal VCA or an output signal VCB.

A charge is realized when the switch (53) is turned on, and a discharge is realized when the switch (53) is turned off in the first average value detector (50). FIG. 7 shows a reversed case of FIG. 6.

The LPF (52) of FIGS. 6 and 7 outputs a width of VCA or a width of VCB by equalizing the width, which is then transmitted to the comparator (70), where the comparator (70) transmits a difference of VCA and VCB to the duty alert clock (10).

This process is repeatedly performed until an output of the comparator (70) becomes zero to generate a stable duty ratio, the explanation of which has been already provided.

That is, the switch (53) is turned on when the VCA is high in FIG. 6, a current of the current source (51) flows to the ground (GND), and an electric charge of an inner capacitor of LPF (52) is discharged. Alternatively, the switch (53) is turned off when the VCA is low, and a current I of the current source (51) charges an electric charge Q to the inner capacitor of the LPF (52) as much as Q=C×Vout A during OFF time, where C is a capacitance of inner capacitor of LPF (52), which may be expressed as Q=I×Toff. Thus, Vout A=(I×Toff/C).

In a configuration of FIG. 7, the turn-on/off operations are reversed from FIG. 6, and may be expressed as Vout B=(I×Ton/C).

Vout A=Vout B in a system having 50% duty ratio.

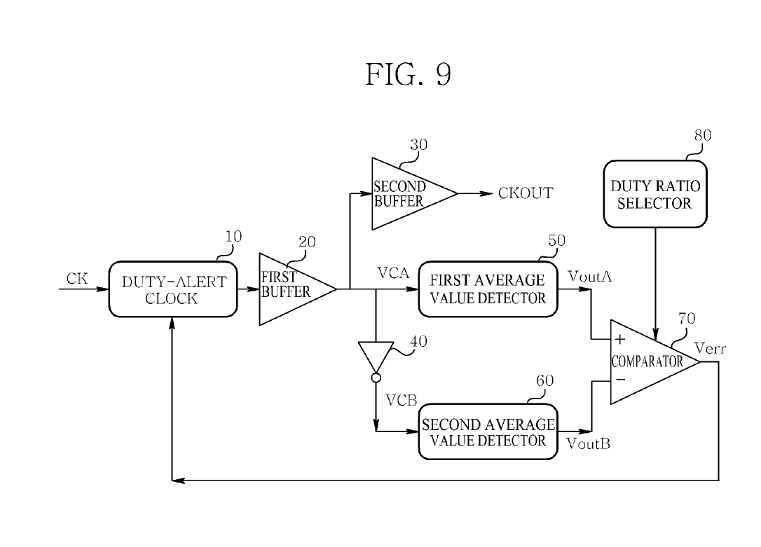

FIG. 9 is a block diagram illustrating a configuration of an apparatus for correcting duty cycle according to a second exemplary embodiment of the present invention.

Referring to FIG. 9, the apparatus according to the present invention may include a duty alert clock (10), a first buffer (20), a second buffer (30), an inverter (40), a first average value detector (50), a second average value detector (60), a comparator (70) and a duty ratio selector (80). The apparatus according to the second exemplary embodiment of the present invention further includes the duty ratio selector (80), in addition to what is configured in the first exemplary embodiment of the present invention of FIG. 3, and explanation of other constituent elements is same as that explained in FIG. 3 such that no further elaboration is omitted.

The duty ratio selector (80) allows the comparator (70) to output based on a relevant ratio by selecting ratio of VCA and VCB which are inputs of the comparator (70), whereby systems of various duty ratios can be realized, and an apparatus having an accurate duty cycle can be designed.

The apparatus for correcting duty cycle according to the present invention has an industrial applicability in that system can be miniaturized and power consumption can be reduced due to non-use of a pulse generator conventionally used in a duty cycle correcting apparatus.

Another industrial applicability is that a delayer that generates an intrinsic delay error is not used to greatly increase accuracy, whereby the present invention can be used for digital and analogue systems, power circuits, synchronous circuits, sensors that require high integrity and low power consumption, RFIDs and tags.

The previous description of the present invention is provided to enable any person skilled in the art to make or use the invention. Various modifications to the invention will be readily apparent to those skilled in the art, and the generic principles defined herein may be applied to other variations without departing from the spirit or scope of the invention. Thus, the invention is not intended to limit the examples described herein, but is to be accorded the widest scope consistent with the principles and novel features disclosed herein.

1. An apparatus for correcting duty cycle, the apparatus configured to correct a duty ratio of an input signal, the apparatus comprising:
an alert clock configured to adjust a signal width of the input signal;
a first equalization unit configured to equalize a width of an output signal of the alert clock;
an inverter configured to reverse the output signal of the alert clock;
a second equalization unit configured to equalize a width of an output signal of the inverter; and
a comparator configured to compare the output signals of the first and second equalization units, and output a difference between the output signals of the first and second equalization units.

2. The apparatus of claim 1, wherein the alert clock is configured to adjust the width of the input signal using an output of the comparator.

3. The apparatus of claim 1, further comprising:
a selector configured to select a ratio of the output signals of the first and second equalization units to allow the comparator to output the difference in response to the ratio.

4. The apparatus of claim 1, further comprising:
a first buffer configured to temporarily store an output of the alert clock and output the output of the alert clock to the first equalization unit.

5. The apparatus of claim 4, wherein the inverter is configured to reverse an output of the first buffer.

6. The apparatus of claim 4, further comprising:
a second buffer configured to temporarily store and output an output of the first buffer.

7. The apparatus of claim 2, wherein the output of the comparator is inputted to the alert clock until the output of the comparator substantially becomes zero, when a duty ratio of the output of the alert clock matches that of the output of the inverter.

8. The apparatus of claim 2, wherein the alert clock comprises:
a controller configured to control the width of input signal in response to the output of the comparator, and
a first switch configured to turn on or off operation of the controller.

9. The apparatus of claim 2, wherein each of the first and second equalization units comprises:
a current source configured to supply a current,
a second switch configured to switch the current supplied from the current source in response to high and low level of an inputted voltage, and
an LPF (Low Pass Filter) configured to equalize a width of the voltage inputted using the current of the current source in response to the switching of the second switch and to output the equalized width.

10. The apparatus of claim 9, wherein the LPF includes a capacitor.
